(19) United States
(12) Patent Application Publication
(10) Pub. No.: US 2024/0258329 A1
(43) Pub. Date: Aug. 1, 2024

(54) DISPLAY APPARATUS

(71) Applicant: LG Display Co., Ltd., Seoul (KR)

(72) Inventors: Soyi LEE, Paju-si (KR); Byunghyun LEE, Paju-si (KR); Yongmin HA, Seoul (KR)

(73) Assignee: LG Display Co., Ltd., Seoul (KR)

(21) Appl. No.: 18/420,293

(22) Filed: Jan. 23, 2024

(30) Foreign Application Priority Data
Jan. 31, 2023 (KR) 10-2023-0013295

(51) Int. Cl. H01L 27/12; H10K 59/90

(52) U.S. Cl. CPC H01L 27/124; H10K 59/90

(57) ABSTRACT

A display apparatus can include a wiring substrate including a first light emitting part and a first transmissive area; a plurality of display units disposed on the wiring substrate, wherein one display unit among the of the plurality of display units includes a second light emitting part and a second transmissive area; a plurality of bonding members disposed between the one display unit and the wiring substrate, and electrically connected to a plurality of link wirings; and a gate driver configured to supply a signal to the one display unit. The first light emitting part of the wiring substrate includes the plurality of link wirings and the gate driver disposed thereon. Further, the second light emitting part of the one display unit includes a plurality of light emitting elements disposed thereon.

### CROSS REFERENCE TO RELATED APPLICATION

This application claims priority to Korean Patent Application No. 10-2023-0013295, filed on Jan. 31, 2023 in the Korean Intellectual Property Office, the entire contents of which is hereby expressly incorporated by reference into the present application.

### BACKGROUND

### Field

The present disclosure relates to a display apparatus, and more specifically, to a display apparatus in which a plurality of display units are disposed on a wiring substrate on which a plurality of link wirings are disposed.

### Discussion of the Related Art

Display apparatuses are widely used in a variety of areas and technologies, and are integral part of our society. For instance, such display apparatuses have been applied to various electronic devices such as TVs, mobile phones, laptops, tablets, smart watches, navigation systems, etc. To this end, research for developing those display apparatuses that are thinner, lighter, and have lower power consumption is being continuously conducted.

Among the display apparatuses, a light emitting display apparatus has a light emitting element or light source built into the display apparatus and displays information using the light generated from the built-in light emitting element or light source. The light emitting element here can be a self-light emitting element since it generates and emits light itself and does not require a separate light source for generating light.

A display apparatus including a self-light emitting element has an advantage since such display apparatus can be manufactured to be thinner than a display apparatus with the built-in light source. Further, the display apparatus including the self-light emitting element is advantageous since it can be flexibly folded, bent, or rolled.

The display apparatus with the self-light emitting element can include, for example, an organic light emitting device (OLED) including an organic material as a light emitting layer, or a micro light emitting diode (micro LED) including an inorganic material as a light emitting layer. When the OLEDs are used in the display apparatus, although the OLED does not require a separate light source, defective pixels can be generated by an external environment due to the material characteristics of the organic material being more vulnerable to moisture and oxygen.

In contrast, when the micro LEDs are used in the display apparatus, since the inorganic material being more resistant to moisture and oxygen is used as the light emitting layer, the micro LED may not be affected by the external environment. As such, the display apparatus using the micro LEDs can have high reliability and a longer lifespan compared to the display apparatus using the OLEDs.

### SUMMARY OF THE DISCLOSURE

The present disclosure is directed to providing a large-area transparent display apparatus by arranging a plurality of display units on a wiring substrate on which a plurality of link wirings and a gate driver are disposed.

In addition, the embodiments of the present disclosure are directed to providing a display apparatus capable of implementing a zero bezel area in which a bezel area is disposed as a minimum space or the bezel area is not substantially present.

In addition, the embodiments of the present disclosure are directed to providing a display apparatus for preventing a degradation in reliability of a product due to the occurrence of a dim defect/issue in which fine vertical lines can be visible in a light emitting part of a display unit.

In addition, the embodiment of the present disclosure are directed to providing a display apparatus capable of increasing a transmittance of a transparent display apparatus by increasing a design margin using a wiring substrate.

Objects according to one or more embodiments of the present disclosure are not limited to the above-described objects, and other objects and advantages of the present invention that are not mentioned can be understood by the following description and will be more clearly understood by the embodiments of the present disclosure. In addition, it will be able to be easily seen that the objects and advantages of the present disclosure can be achieved by devices and combinations thereof that are described in the claims.

A display apparatus according to one embodiment of the present disclosure includes a wiring substrate including a light emitting part on which a plurality of link wirings and a gate driver are disposed and a transmissive area, a plurality of display units including a light emitting part on which a plurality of light emitting elements are disposed and a transmissive area and disposed to be spaced apart from each other on the wiring substrate, and a plurality of bonding members disposed between the display unit and the wiring substrate and connected to a gate driver and a plurality of link wirings.

A display apparatus according to one embodiment of the present disclosure includes a wiring substrate including a first light emitting part and a first transmissive area; a plurality of display units disposed on the wiring substrate, wherein one display unit among the of the plurality of display units includes a second light emitting part and a second transmissive area; a plurality of bonding members disposed between the one display unit and the wiring substrate, and electrically connected to a plurality of link wirings; and a gate driver configured to supply a signal to the one display unit, wherein the first light emitting part of the wiring substrate includes the plurality of link wirings and the gate driver disposed thereon, and wherein the second light emitting part of the one display unit includes a plurality of light emitting elements disposed thereon.

A display apparatus according to one embodiment of the present disclosure includes a wiring substrate including light emitting areas and transmissive areas disposed in an alternating manner; a plurality of display units disposed on the wiring substrate, and connected with the wiring substrate via at least one bonding member; a plurality of link lines provided to correspond with each of the plurality of display units, and disposed between the plurality of display units and the wiring substrate; and a plurality of gate drivers provided to correspond with each of the plurality of display units, and disposed between the plurality of display units and the wiring substrate, wherein one of the plurality of gate drivers and one or more of the plurality of link lines are disposed in one of the light emitting areas.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a schematic plan view of a display apparatus according to one embodiment of the present disclosure.

FIG. 2 is a schematic plan view of a wiring substrate according to one embodiment of the present disclosure.

FIG. 3 is a cross-sectional view of portion 3 in FIG. 1.

FIG. 4 is a plan view of portion 4 in FIG. 2.

FIG. 5 is a plan view of a partial area of a display unit.

FIG. 6 is a plan view of a partial area of the display apparatus according to one embodiment of the present disclosure.

FIG. 7 is a cross-sectional view of portion 7 in FIG. 5.

FIGS. 8 to 13 are views illustrating a display apparatus according to another embodiment of the present disclosure.

### DETAILED DESCRIPTION OF THE EMBODIMENTS

Advantages and features of the present disclosure and methods for achieving them will become clear with reference to embodiments described below in detail in conjunction with the accompanying drawings. However, the present disclosure is not limited to the embodiments disclosed below but will be implemented in various different forms, these embodiments are merely provided to make the disclosure of the present disclosure complete and fully inform those skilled in the art to which the present disclosure pertains of the scope of the present disclosure.

Since shapes, sizes, ratios, angles, numbers, and the like disclosed in the drawings for describing the embodiments of the present disclosure are illustrative, the present disclosure is not limited to the illustrated items. The same reference number indicates the same components throughout the present disclosure. In addition, in describing the present disclosure, when it is determined that the detailed description of a related known technology can unnecessarily obscure the gist of the present disclosure, detailed description thereof will be omitted.

When terms “comprises,” “has,” “includes,” “consists of,” and the like described in the present disclosure are used, other parts can be added unless “only” is used. When a component is expressed in the singular, it includes a case in which the component is provided as a plurality of components unless specifically stated otherwise.

In construing a component, the component is construed as including the margin of error even when there is no separate explicit description.

When the positional relationship is described, for example, when the positional relationship between two parts is described using the term “on,” “above,” “over,” “under,” “below,” “next to,” or the like, one or more other parts can be positioned between the two parts unless the term “immediately” or “directly” is used.

When the temporal relationship is described, for example, when the temporal relationship is described using the term “after,” “subsequently,” “then,” “before,” or the like, it can include a non-consecutive case unless the term “immediately” or “directly” is used.

Although first, second, and the like are used to describe various components, these components are not limited by these terms. These terms are only used to distinguish one component from another and may not define order or sequence. Therefore, a first component described below can be a second component within the technical spirit of the present disclosure.

Features of various embodiments of the present disclosure can be coupled or combined partially or entirely, and various technological interworking and driving are possible, and the embodiments can be implemented independently of each other or implemented together in an associated relationship.

Hereinafter, a display apparatus according to each embodiment of the present invention will be described with reference to the accompanying drawings. All the components of each display apparatus or display device according to all embodiments of the present disclosure are operatively coupled and configured.

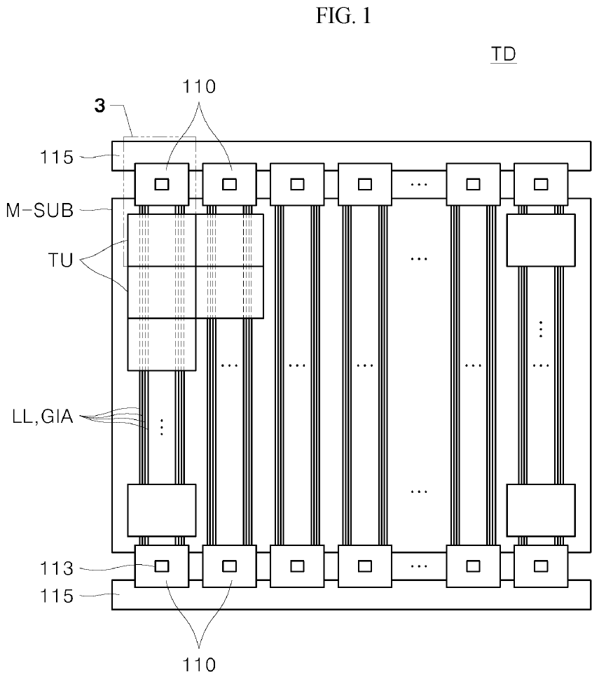

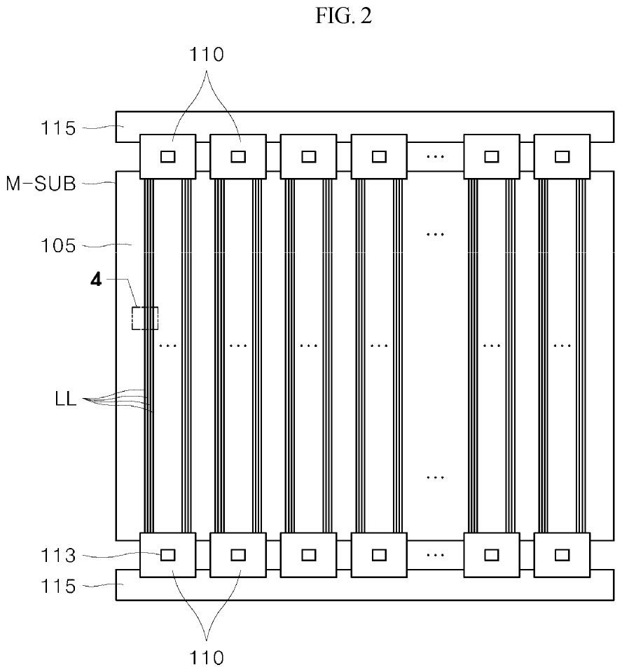

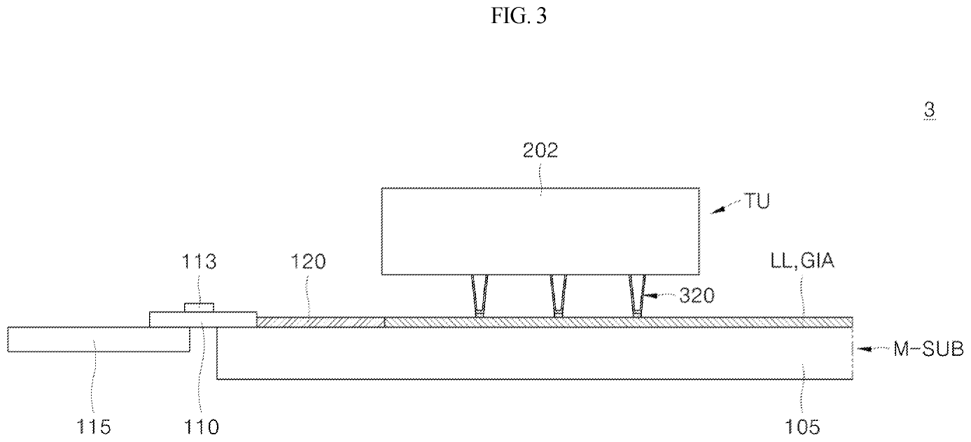

FIG. 1 is a schematic plan view of a display apparatus according to one embodiment of the present disclosure. FIG. 2 is a schematic plan view of a wiring substrate of the display apparatus according to one embodiment of the present disclosure. In addition, FIG. 3 is a cross-sectional view of portion 3 in FIG. 1.

In FIG. 1, for convenience of description, a wiring substrate M-SUB, a plurality of link wirings LL, a gate driver GIA, a plurality of circuit films 110 on which an integrated circuit chip 113 is disposed, a printed circuit board 115, and a plurality of display units TU are merely illustrated among various components of a display apparatus TD. Further, in FIG. 2, the plurality of display units TU are intentionally removed to more clearly show the display apparatus of FIG. 1 including the wiring substrate M-SUB. In addition, FIG. 3 illustrates an example of one display unit TU disposed on the wiring substrate M-SUB in the display apparatus according to one embodiment of the present disclosure.

Referring to FIGS. 1 to 3, the display apparatus TD according to one embodiment of the present disclosure can be a tiling display apparatus TD including the plurality of display units TU disposed on the wiring substrate M-SUB. The display units TU can be disposed adjacent to each other in a first direction and a second direction crossing the first direction. Here, the first direction can be a horizontal direction, and the second direction can be a vertical direction. However, the first and second directions can be the vertical and horizontal directions, respectively, or other variations are possible. Further, the display units TU can be disposed immediately next to each other so that one or more large screen can be formed.

In addition, any number of the display units TU in various configurations and shapes can be used in the display apparatus of the present disclosure.

Each of the display units TU can be electrically connected to the wiring substrate M-SUB through a bonding member 320. The bonding member 320 will be discussed later in more detail. The display units TU can each include a plurality of sub-pixels, and can each be a display device or module configured to display an image. A first substrate 105 of the wiring substrate M-SUB and a second substrate 202 of the display unit TU can include glass or transparent plastic. A large-area (or large-sized) transparent display apparatus can be provided or implemented by arranging the plurality of display units TU adjacent to each other on an upper surface of the wiring substrate M-SUB.

The plurality of link wirings LL and the gate driver GIA can be disposed on the wiring substrate M-SUB. The plurality of link wirings LL can be disposed in one direction of the wiring substrate M-SUB. For instance, the plurality of link wirings LL can extend along the vertical direction between the circuit films 110 disposed on opposite sides of the display apparatus TU. The plurality of link wirings LL can be referred to as link lines or the like.

In the display apparatus TU, a driving unit including the printed circuit board 115 connected to a circuit film 110 on which the integrated circuit chip 113 for transmitting various signals to sub-pixels of each of the display units TU is mounted can be disposed on at least one end portion of the wiring substrate M-SUB.

The driving unit including the printed circuit board 115 can be connected to end portions of the link wiring LL and the gate driver GIA, through a plurality of connecting electrodes 120. Signals transmitted to the sub-pixels, e.g., by the driving unit, can include, for example, a high-potential voltage, a low-potential voltage, a scan signal, a data signal, etc. An output transmitted from the gate driver GIA can include an output voltage or the like capable of driving a gate line connected to a thin film transistor disposed on the display unit TU.

The embodiments of the present disclosure present a configuration in which the driving unit including the printed circuit board 115 connected to the circuit film 110 on which the integrated circuit chip 113 is mounted is disposed on both end portions of the wiring substrate M-SUB. However, other variations are possible.

The plurality of link wirings LL can transmit various signals transmitted from the driving unit to a plurality of signal wirings disposed in each of the display units TU. For example, the signal wiring can include a high-potential voltage line, a low-potential voltage line, a scan line, a data line, etc., but is not limited thereto.

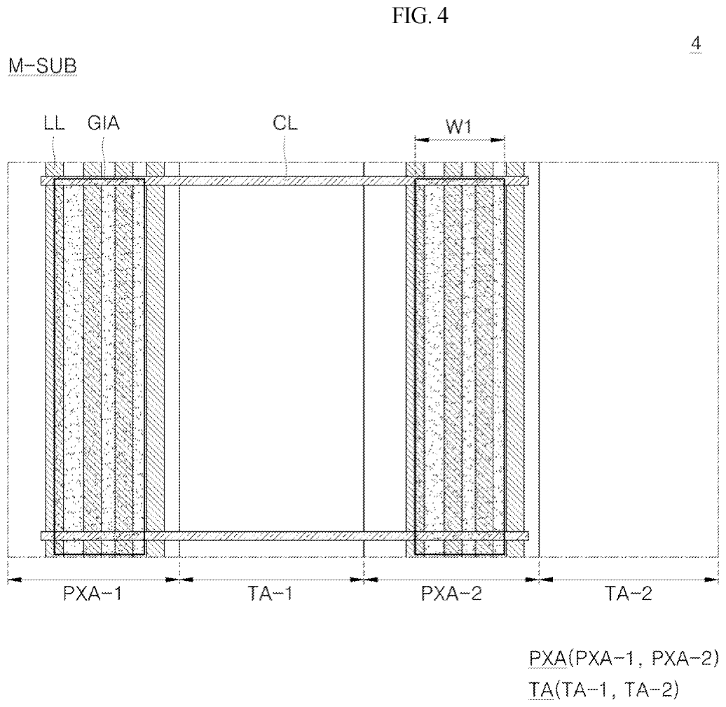

The plurality of display units TU disposed on the wiring substrate M-SUB can be connected to the wiring substrate M-SUB through the electrical connection between the plurality of signal wirings and the plurality of link wirings LL and the gate driver GIA disposed on the wiring substrate M-SUB. Here, the plurality of link wirings LL are disposed to overlap with the plurality of display units TU and may not be exposed to the outside. Therefore, it is possible to decrease an area of a circuit area in which the plurality of link wirings LL are disposed and to increase a display area of the display apparatus TU. Description regarding these features will be made in more detail with reference to FIGS. 4 to 6 below.

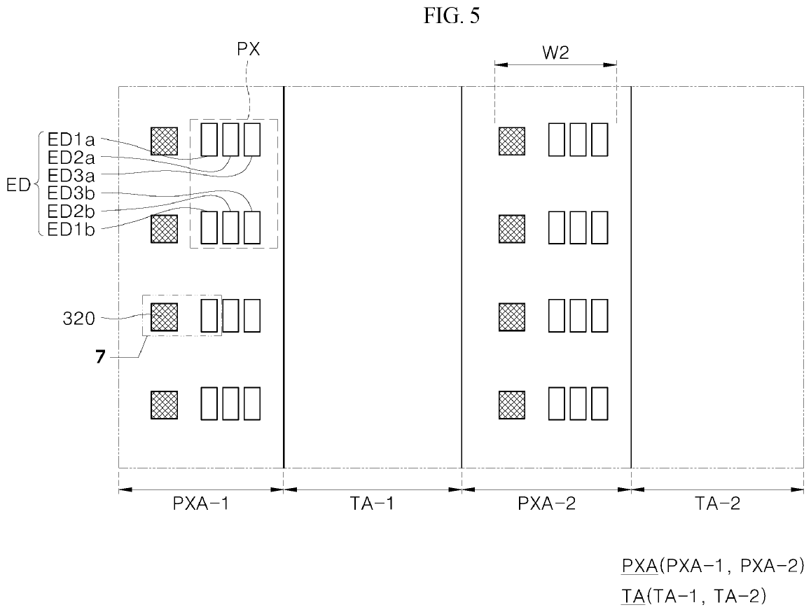

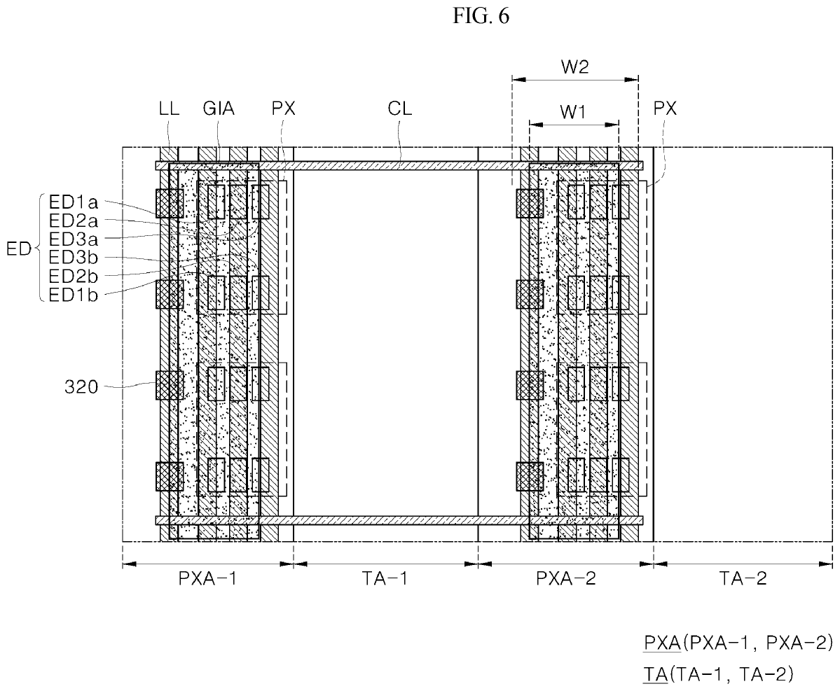

FIG. 4 is a plan view of portion 4 in FIG. 2. FIG. 5 is a plan view of a partial area of a display unit (e.g., TU) of a display apparatus according to an example of the present disclosure. FIG. 5 shows to focus on the area of the display unit TU, which corresponds to the area (portion 4) of the wiring substrate M_SUB focused in FIG. 4. In addition, FIG. 6 is a plan view of a partial area of the display apparatus according to one embodiment of the present disclosure, and shows the combined view of the areas of FIGS. 4 and 5.

Referring to FIGS. 4 to 6, a first area of the wiring substrate M-SUB can include one or more of light emitting parts PXA, and a second area of the wiring substrate M-SUB can include one or more of transmissive areas TA. The light emitting parts PXA can be referred as light emitting areas PXA. The first area and the second area can be positioned alternately. For example, the light emitting parts PXA and the transmissive areas TA can be alternatingly disposed. The light emitting part PXA, which is or corresponds to the first area of the wiring substrate M-SUB, can be divided in a unit of block. For example, the light emitting part PXA can include a first light emitting part PXA-1 positioned in a first block, and a second light emitting part PXA-2 positioned in a second block.

The transmissive area TA, which is or corresponds to the second area of the wiring substrate M-SUB, can be divided in a unit of block. For example, the transmissive area TA can include a first transmissive area TA-1 positioned in the first block, and a second transmissive area TA-2 positioned in the second block. In the example of FIG. 4, for convenience of description, the first block and the second block are illustrated, but a plurality of such blocks including a plurality of the first blocks and a plurality of the second blocks can be disposed.

The first transmissive area TA-1 can be disposed between the first light emitting part PXA-1 and the second light emitting part PXA-2, and the second transmissive area TA-2 can be disposed between the second light emitting part PXA-2 and a light emitting part positioned in a different next block (e.g., third block or another first block).

Each of the light emitting parts PXA disposed in the first area of the wiring substrate M-SUB can be positioned to correspond to one of the light emitting parts PXA disposed in the first area of the display unit TU, and each of the transmissive areas TA disposed in the second area of the wiring substrate M-SUB can be positioned to correspond to one of the transmissive areas TA disposed in the second area of the display unit TU.

The transmissive area TA can be an area in which an opaque material or a reflective material is not disposed. The display apparatus TD according to the embodiment of the present disclosure can secure a transmittance through the transmissive area TA. Therefore, the display apparatus TD can be a transparent display apparatus in which objects or images disposed on a back surface (or a rear surface) of the display apparatus is visible through the transmissive area TA.

The link wirings LL and the gate driver GIA disposed in one direction of the wiring substrate M-SUB (e.g., along the vertical direction in FIG. 4) can be disposed on the light emitting part PXA of the wiring substrate M-SUB. The gate driver GIA supplies signals for driving the gate lines for the display units TU.

One of the methods of arranging the gate driver is a method of arranging the gate driver by a gate-in-panel (GIP) method in each of the display units TU. The gate driver (e.g., GIA) disposed by the GIP method is disposed in a bezel area outside both sides of each of the display units TU to compensate for a short charging time of each gate line to provide the same gate output to both ends of each gate line.

However, according to a comparative example, in a tiling display apparatus including a plurality of display units disposed on a wiring substrate, adjacent display units are disposed in contact with each other in the first direction and the second direction crossing the first direction. In the configuration in which the adjacent display units are disposed in contact with each other, if the gate driver is disposed in a bezel area at both sides of each of the display units, an opaque area of the bezel area can increase. Then, in such configuration, the bezel area can be visible to the user, which can degrade image quality. Therefore, it can be challenging or difficult to implement a tiling display apparatus.

Thus, in another comparative example, instead of arranging the gate driver in the bezel area, there is a proposed method of arranging the gate driver in the display unit to be distributed. For example, there is a proposed method of arranging a plurality of gate drivers to be distributed in a space between the light emitting parts on the display unit. However, if the gate drivers are disposed to be distributed between the light emitting parts on the display unit, the transparent area can be reduced, which can reduce transmittance. Further, a dim defect or issue in which fine vertical lines are visible can occur in areas in which the gate drivers are disposed to be distributed.

Therefore, to address these issues associated with the comparative examples, in the embodiment of the present disclosure, by introducing the configuration in which the gate driver GIA is disposed on the light emitting part PXA of the wiring substrate M-SUB, it is possible to provide an improved tiling display apparatus and to prevent the occurrence of any dim defect in which a boundary area between the adjacent display units TU may be visible to the user.

Referring back to FIG. 4, the gate driver GIA is illustrated as a box having scattered dots, and can be disposed on the first light emitting part PXA-1 positioned in the first block of the wiring substrate M-SUB and on the second light emitting part PXA-2 positioned in the second block in a unit of block. The gate driver GIA can include a plurality of thin film transistors for driving each of the gate lines.

The gate driver GIA disposed in a unit of block can have a size of a first width W1 on the first light emitting part PXA-1 positioned in the first block, and the gate driver GIA disposed in a unit of block can also have a size of the same first width W1 on the second light emitting part PXA-2 positioned in the second block. Such gate drivers GIA disposed in adjacent blocks can be electrically connected to each other through a (horizontal) connection wiring (or connecting line) CL. For example, the horizontal connection wiring CL can be electrically connected to the gate driver GIA disposed on the second light emitting part PXA-2 positioned in the second block after horizontally crossing the first transmissive area TA-1 from the gate driver GIA disposed on the first light emitting part PXA-1 positioned in the first block. One or more connecting wirings CL can be used to connect the adjacent gate drivers GIA.

Referring to FIGS. 5 and 6, each of the display units TU disposed on the wiring substrate M-SUB can include a light emitting part PXA corresponding to each of the light emitting part PXA disposed in the first area of the wiring substrate M-SUB, and further includes a transmissive area TA corresponding to each of the transmissive area TA disposed in the second area of the wiring substrate M-SUB.

The light emitting part PXA and the transmissive area TA of the display unit TU can be divided in a unit of block. For example, the light emitting part PXA can include a first light emitting part PXA-1 positioned in a first block, and a second light emitting part PXA-2 positioned in a second block. For example, the transmissive area TA of the display unit TU can include a first transmissive area TA-1 positioned in the first block, and a second transmissive area TA-2 positioned in the second block. In FIG. 5, for convenience of description, the first block and the second block of the display unit TU are illustrated, but the display unit TU can include a plurality of such first blocks and a plurality of such second blocks.

Various circuit elements including a light emitting element ED and a driving thin film transistor for driving the light emitting element ED can be disposed on each light emitting part PXA of each display unit TU. The transmissive area TA of each display unit TU can be an area in which an opaque material or a reflective material is not disposed.

The light emitting part PXA of each display unit TU can include a pixel area PX in which a plurality of light emitting elements ED are disposed. One pixel area PX can be understood as one group including a plurality of sub-pixels. The light emitting element ED disposed in the pixel area PX of each display unit TU can include at least one light emitting element disposed in each sub-pixel. For example, the light emitting element ED can include at least one of a first light emitting element ED1a, a second light emitting element ED2a, or a third light emitting element ED3a, which are main light emitting elements for emitting light of red (R), green (G), and blue (B), respectively, but is not limited thereto. These light emitting elements can emit other colors or other combinations of colors.

In addition, each of the plurality of sub-pixels can further include a plurality of redundancy light emitting elements ED1b, ED2b, and ED3b for a repair process. For example, the redundancy light emitting elements ED1b, ED2b, and ED3b can include at least one of a first redundancy light emitting element ED1b, a second redundancy light emitting element ED2b, or a third redundancy light emitting element Ed3b, respectively corresponding to the first light emitting element ED1a, the second light emitting element ED2a, or the third light emitting element ED3a to emit light of the same color as the main light emitting element. For example, each pixel area PX can include the first to third light emitting elements ED1a, ED2a, ED3a and the first to third redundancy light emitting elements ED1b, ED2b, ED3b.

The bonding member 320 can also be disposed on the light emitting part PXA of the display unit TU. Referring to FIG. 6, the bonding member 320 can be disposed to overlap the link wiring LL disposed on the wiring substrate M-SUB.

The bonding member 320 can be disposed to overlap the plurality of link wirings LL on the wiring substrate M-SUB to electrically connect the wiring substrate M-SUB to each of the display units TU on upper and lower portions thereof. For example, the bonding member 320 can function to transmit various signals transmitted through the link wirings LL to the light emitting element ED or the driving thin film transistor TFT of the display unit TU. It is possible to achieve process optimization by electrically connecting the wiring substrate M-SUB to the plurality of display units TU using the bonding member 320 without using a separate side wiring. As such, the bonding member 320 can include a conductive material.

An area including the pixel area PX in which the plurality of light emitting elements ED of the display unit TU are disposed and the bonding member 320 can have a size of a second width W2. The gate driver GIA disposed in a unit of block on the wiring substrate M-SUB can have the size of the first width W1 in each of the light emitting parts PXA-1 and PXA-2 and have a smaller width than the light emitting part on which the plurality of light emitting elements are disposed. For example, the gate driver GIA can have a smaller size than the second width W2 of the area including the pixel area PX in which the plurality of light emitting elements ED of the display unit TU are disposed and the bonding member 320. The width W2 is greater than the width W1, and the size of the area of the gate driver GIA can be less than the size of the area including the pixel area PX and the bonding member 320. Therefore, it is possible to prevent a reduction in luminance by preventing a reduction in aperture ratio.

Further, the gate driver GIA can be disposed on the light emitting part PXA of the wiring substrate M-SUB to overlap the light emitting part PXA of the display unit TU. Therefore, it is possible to increase a design margin of the light emitting part PXA of the display unit TU as much as a size of the area of the area in which the gate driver GIA is disposed.

For example, in a comparative example, if a plurality of gate drivers are disposed to be distributed in a space between the light emitting parts on the display unit, an area in which circuit elements (e.g., transistors) are disposed can be reduced as much as the area of the area in which the gate driver is disposed. In addition, coupling limitation can occur between a connection wiring connecting the gate drivers disposed in adjacent blocks to a data line, which is one of the signal lines due to a parasitic capacitor. Then, a spatial margin between adjacent circuit elements can be reduced, which can cause capacitor coupling or parasitic capacitor deviation for each position. The capacitor coupling or parasitic capacitor deviation for each position can cause luminance deviation in which luminance appears differently for each position in the light emitting part, which can result in a dim defect/issue in which fine vertical lines can be visible on the light emitting part. The dim issue can degrade image quality, which can degrade the reliability of display device products.

In contrast to the above comparative example, according to the embodiment of the present disclosure, by arranging the gate driver GIA at a position overlapping the light emitting part PXA of the display unit TU on the light emitting part PXA of the wiring substrate M-SUB, the design margin can be increased, thereby preventing the occurrence of the capacitor coupling or the parasitic capacitor deviation for each position. Therefore, it is possible to prevent the occurrence of any dim defect/issue in the light emitting part due to the luminance deviation for each position, thereby improving the reliability of the display apparatus.

In addition, according to the embodiment of the present disclosure, the gate driver GIA can be disposed in a shape of a driving circuit disposed in the pixel area PX of the display unit TU.

In addition, according to the embodiment of the present disclosure, by arranging the gate driver GIA on the light emitting part PXA of the wiring substrate M-SUB (e.g., instead of arranging the gate driver in the bezel area outside both sides of the display unit as in the comparative example), it is possible to implement a zero bezel area in which the bezel area of the display unit TU is disposed as the minimum space or the bezel area is not substantially present, which is advantageous.

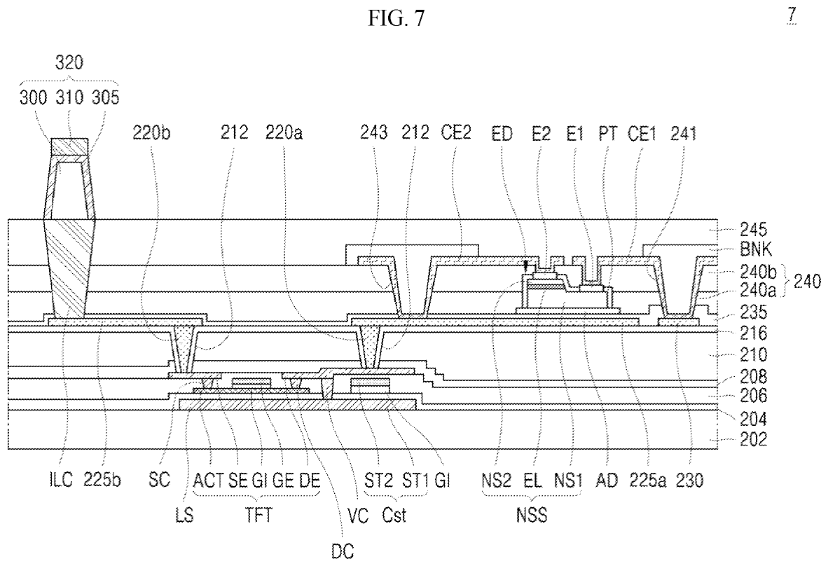

The plurality of pixel areas PX and the bonding member 320 can be disposed on the light emitting part PXA of the display unit TU. A driving circuit including a light emitting element and a thin film transistor for driving the light emitting element can be disposed in each of the plurality of pixel areas PX. Hereinafter, description thereof will be made with reference to FIG. 7.

FIG. 7 is a cross-sectional view of portion 7 in FIG. 5. Particularly, FIG. 7 illustrates a light emitting element and a thin film transistor disposed in one sub-pixel for convenience of description. Each of the sub-pixels can include the same components.

Referring to FIG. 7, one sub-pixel according to the embodiment of the present disclosure can include a thin film transistor TFT, a storage capacitor Cst, and various wirings disposed on the second substrate 202. The thin film transistor TFT can drive the light emitting element ED, and the storage capacitor Cst can store a voltage so that the light emitting element ED continuously maintains the same state for one frame.

A light shielding layer LS can be disposed on the second substrate 202. The light shielding layer LS can reduce a leakage current by shielding light entering from a lower portion of the second substrate 202 to an active layer of the plurality of transistors. For example, the light shielding layer LS can be disposed under an active layer ACT of the thin film transistor TFT functioning as the driving transistor to shield the light entering the active layer ACT.

A buffer layer 204 is disposed on the light shielding layer LS. The buffer layer 204 can prevent impurities or moisture from entering through the second substrate 202. The buffer layer 204 can include, for example, an insulating material such as silicon oxide (SiOₓ) or silicon nitride (SiNₓ).

The thin film transistor TFT is disposed on the buffer layer 204. The thin film transistor TFT can include the semiconductor layer (active layer) ACT, a gate electrode GE, a source electrode SE, and a drain electrode DE. A gate insulating layer GI can be disposed between the semiconductor layer ACT and the gate electrode GE.

The semiconductor layer ACT can include an active area that overlaps the gate electrode GE to form a channel and a source area and a drain area positioned at both sides with the active area interposed therebetween. An interlayer insulating film 206 is disposed on the gate electrode GE. The interlayer insulating film 206 can include a source contact SC and a drain contact DC. The source contact SC and the drain contact DC can be connected to the source electrode SE and the drain electrode DE positioned above the interlayer insulating film 206, respectively and electrically connected to the source area and the drain area of the semiconductor layer ACT, respectively.

The storage capacitor Cst can include a first capacitor electrode ST1 and a second capacitor electrode ST2. The first capacitor electrode ST1 can be disposed between the second substrate 202 and the buffer layer 204. The first capacitor electrode ST1 can be formed integrally with the light shielding layer LS. The buffer layer 204 and the gate insulating layer GI can be disposed as dielectrics on the first capacitor electrode ST1. The second capacitor electrode ST2 can be disposed on the gate insulating layer GI, so that the gate insulating layer GI is disposed between the first and second capacitor electrodes ST1 and ST2. The second capacitor electrode ST2 can be made of the same material as the gate electrode GE.

A first passivation layer 208 is disposed on the source electrode SE and the drain electrode DE. The first passivation layer 208 can protect the thin film transistor TFT and include an insulating material. A first planarization layer 210 is disposed on the first passivation layer 208. The first planarization layer 210 functions to planarize a step difference between surfaces caused by a lower structure such as the thin film transistor TFT. The first planarization layer 210 can include a photoactive compound PAC, but is not limited thereto.

The first planarization layer 210 can include a contact hole 212 exposing portions of the surfaces of the source electrode SE and the drain electrode DE of the thin film transistor TFT. A second passivation layer 216 can be disposed on the first planarization layer 210 including the contact hole 212, and via contacts 220a and 220b can be disposed to fill each of the contact holes 212. The via contacts 220a and 220b can include a first via contact 220a and a second via contact 220b.

A first connection electrode 225a connected to the first via contact 220a and a second connection electrode 225b connected to the second via contact 220b can be disposed on the second passivation layer 216. The drain electrode DE connected to the first via contact 220a can be electrically connected to the light shielding layer LS through a through electrode VC that passes through the interlayer insulating film 206 and the buffer layer 204.

The first connection electrode 225a, the second connection electrode 225b, and a signal wiring 230 can be positioned on the same plane. The third passivation layer 235 can expose an upper surface of each of the first connection electrode 225a, the second connection electrode 225b, and the signal wiring 230. The signal wiring 230 can include a plurality of signal wirings. For example, the plurality of signal wirings can include a plurality of scan lines, a plurality of high-potential voltage Vdd lines, a plurality of data lines, and a plurality of reference voltage lines. The plurality of signal wirings can be disposed on the same plane on the second substrate 202. In addition, the plurality of signal wirings can be made of the same material as the first connection electrode 225a and the second connection electrode 225b.

An adhesive layer AD is disposed on the third passivation layer 235. The adhesive layer AD functions to bond the light emitting element ED. The adhesive layer AD can be made of a heat-curable material or a light-curable material, but is not limited thereto.

The light emitting element ED can be disposed on the adhesive layer AD. The light emitting element ED according to the embodiment of the present disclosure can be a micro LED. Micro LED is an LED made of an inorganic material and can be understood as a light emitting element of 100 μm or less. In addition, in the embodiment of the present disclosure, a horizontal micro LED is described as an example, but is not limited thereto. For example, the light emitting element can be a vertical micro LED, a flip chip-shaped micro LED, a nanorod-shaped micro LED, or other suitable type.

The light emitting element ED can include a nitride semiconductor structure NSS, a first electrode E1, and a second electrode E2. The nitride semiconductor structure NSS can include a first semiconductor layer NS1, an active layer EL disposed at one side of the first semiconductor layer NS1, and a second semiconductor layer NS2. The first electrode E1 is disposed on the first semiconductor layer NS1 on which the active layer EL is not positioned, and the second electrode E2 is disposed on the second semiconductor layer NS2.

The first semiconductor layer NS1 is a layer for supplying electrons to the active layer EL and can include a nitride semiconductor containing a first conductivity type impurity. For example, the first conductivity type impurity can include an N-type impurity. The active layer EL disposed at the one side of the first semiconductor layer NS1 can include a multi quantum well (MQW) structure. The second semiconductor layer NS2 is a layer for injecting holes into the active layer EL. The second semiconductor layer NS2 can include a nitride semiconductor containing second conductivity type impurities. For example, the second conductivity type impurity can include a P-type impurity. Other variations are possible.

A protective layer pattern PT can cover the outside of the light emitting element ED. The protective layer pattern PT functions to supplement the characteristics of the element by preventing damage that can occur on a side surface of the nitride semiconductor structure NSS in a dry etching process performed to form the nitride semiconductor structure NSS.

The light emitting element ED can be covered by a second planarization layer 240. The second planarization layer 240 can have a thickness sufficient enough to planarize an upper surface having a step difference due to circuit elements. The second planarization layer 240 can include opening holes 241 and 243. The opening holes 241 and 243 can include a first opening hole 241 and a second opening hole 243. In addition, the second planarization layer 240 can expose portions of the upper surfaces of the first electrode E1 and the second electrode E2 of the light emitting element ED. The first electrode E1 and the second electrode E2 can be electrically connected to a first wiring electrode CE1 and a second wiring electrode CE2, respectively.

The first wiring electrode CE1 can extend to an exposed surface of the first opening hole 241, and the second wiring electrode CE2 can extend to an exposed surface of the second opening hole 243. The first wiring electrode CE1 can be electrically connected to the signal wiring 230. The second wiring electrode CE2 can be electrically connected to the drain electrode DE through the first connection electrode 225a.

The first wiring electrode CE1 and the second wiring electrode CE2 can be disposed on the same layer and made of the same conductive material. In one example, the first wiring electrode CE1 and the second wiring electrode CE2 can include a transparent metal oxide such as indium-tin-oxide (ITO) or indium-zinc-oxide (IZO).

A bank BNK can be disposed on the second planarization layer 240. The bank BNK can be made of an opaque material, but is not limited thereto. The first opening hole 241 and the second opening hole 243 can be filled with a material forming the bank BNK. In addition, the bank BNK can be disposed in a nearby area of the light emitting element ED except for the area in which the light emitting element ED is disposed.

A protective layer 245 can be disposed on the second planarization layer 240 including the bank BNK. The protective layer 245 can prevent impurities from entering the light emitting element ED.

An interlayer connection electrode ILC that passes through the protective layer 245 and the second planarization layer 240 and exposes a portion of a surface of the second connection electrode 225b can be disposed. The interlayer connection electrode ILC can be electrically connected to the thin film transistor TFT of the display unit TU through the second connection electrode 225b.

The bonding member 320 can be disposed on the protective layer 245. The bonding member 320 can include a spacer pattern 300, a conductive connection pattern 305, and an adhesive pattern 310. The spacer pattern 300 can function to maintain and support a gap between the wiring substrate M-SUB and the display unit TU. The spacer pattern 300 can have a regular taper shape in which a lower surface has a greater width than an upper surface, but is not limited thereto. The spacer pattern 300 can be a layer in a specific shape.

An outer surface of the spacer pattern 300 can be covered by the conductive connection pattern 305. For example, the conductive connection pattern 305 can be disposed to cover an upper surface of the spacer pattern 300 and surround the outer surface thereof. In addition, the conductive connection pattern 305 can be electrically connected to the thin film transistor TFT through the interlayer connection electrode ILC.

The adhesive pattern 310 can be disposed on the conductive connection pattern 305 covering the upper surface of the spacer pattern 300. The adhesive pattern 310 can be fixed by bonding the wiring substrate M-SUB and the display unit TU.

In addition, the adhesive pattern 310 can transmit the driving signal transmitted through the link wiring LL of the wiring substrate M-SUB to the thin film transistor TFT and provide electrical conductivity to allow the light emitting element on the display unit TU to emit light. To this end, the adhesive pattern 310 can be made of a material that has electrical conductivity and adhesive properties. For example, the adhesive pattern 310 can include an anisotropic conductive film (ACF).

The electrically conductive bonding member 320 functions as a connection wiring for electrically transmitting the output transmitted from the gate driver GIA disposed on the wiring substrate M-SUB to the display unit TU and driving the gate line connected to the thin film transistor disposed on the display unit TU.

In the display apparatus according to one embodiment of the present disclosure, by arranging the gate driver GIA on the light emitting part PXA of the wiring substrate M-SUB overlapping the light emitting part PXA of the display unit TU, it is possible to increase the design margin of the light emitting part PXA of the display unit TU. In addition, by arranging the gate driver GIA on the light emitting part PXA of the wiring substrate M-SUB, it is possible to prevent a dim defect in which fine vertical lines can be visible on the light emitting part of the display unit TU, from occurring and being visible to the user. Therefore, it is possible to improve the product reliability of the display apparatus.

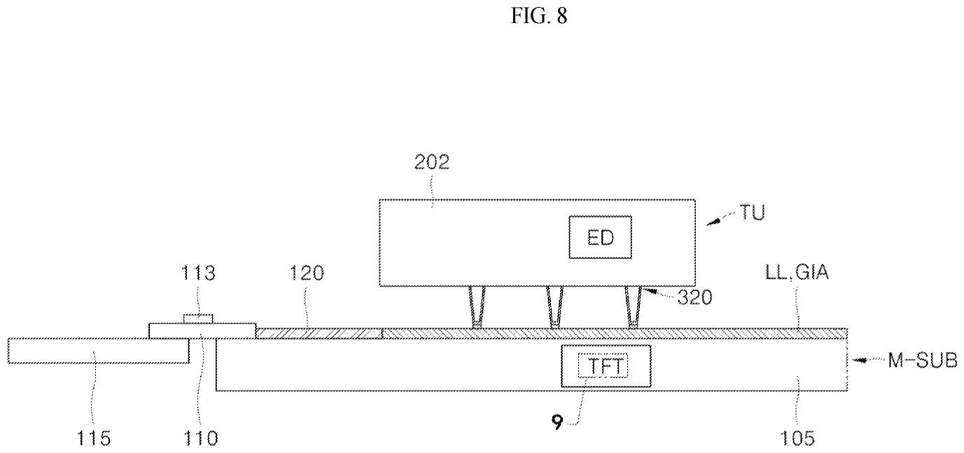

Meanwhile, by arranging the driving transistor TFT occupying a large design area and the storage capacitor Cst on the light emitting part of the wiring substrate M-SUB, it is possible to minimize any influence of a coupling phenomenon which can be present between the signals supplied to the sub-pixels, thereby preventing a crosstalk defect/issue. Hereinafter, description thereof will be made with reference to FIGS. 8 to 13 according to one or more aspect of the present disclosure.

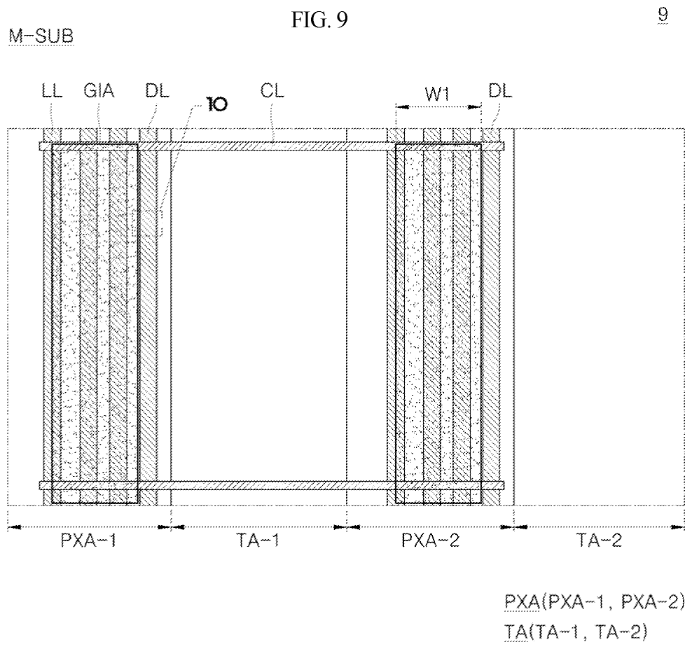

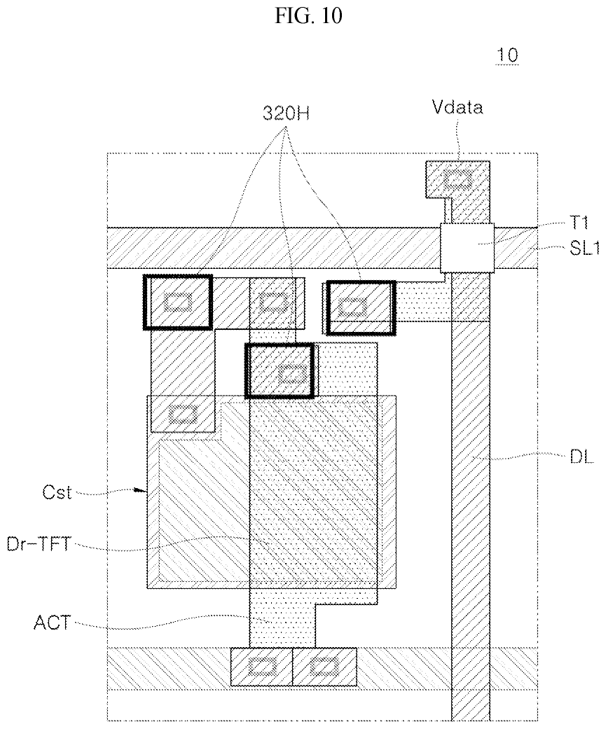

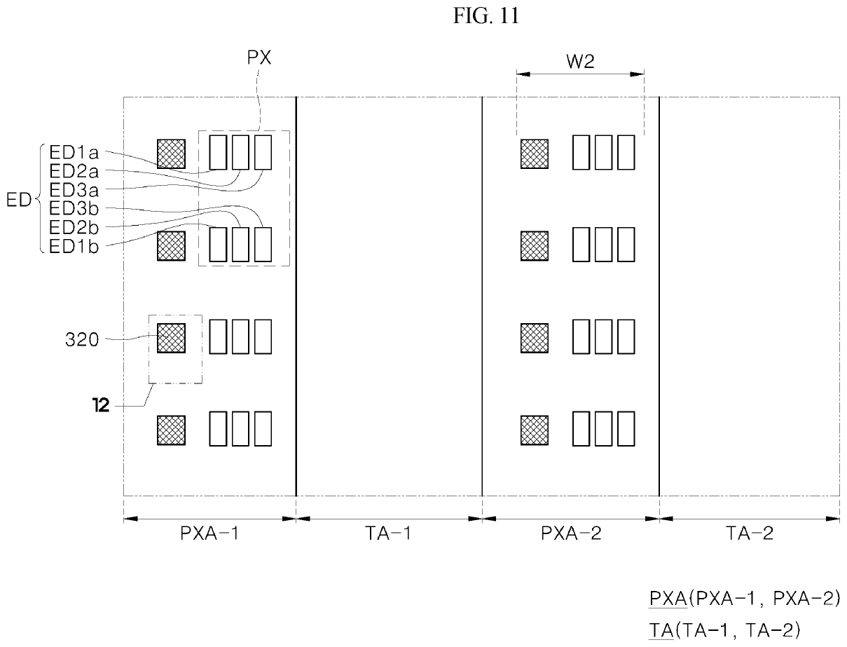

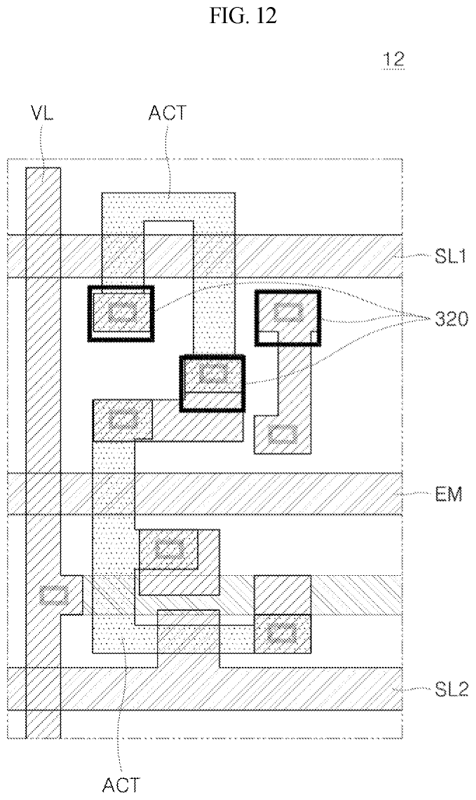

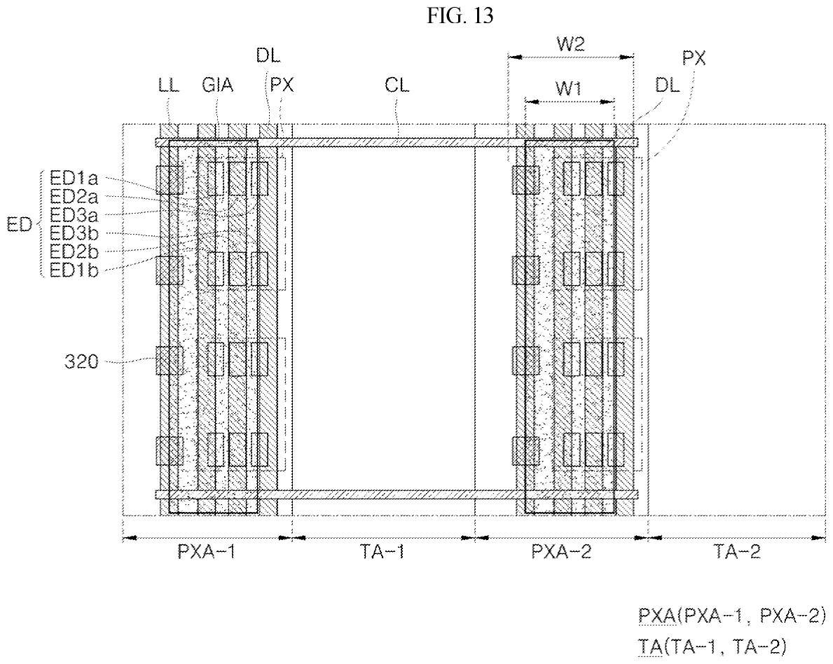

FIGS. 8 to 13 are views illustrating a display apparatus according to another embodiment of the present disclosure. Particularly, FIG. 8 illustrates an example of one display unit TU disposed on the wiring substrate M-SUB in the display apparatus according to this another embodiment of the present disclosure. FIG. 9 is a plan view of portion 9 in FIG. 8. FIG. 10 is a plan view of portion 10 in FIG. 9. FIG. 11 is a plan view of a partial area of the display unit of the display apparatus, which corresponds to the area of FIG. 9. FIG. 12 is a plan view of portion 12 in FIG. 11. In addition, FIG. 13 is a plan view of a partial area of a state in which the display unit has been bonded to the wiring substrate, which corresponds to the area of FIGS. 9 and 11.

Here, other components of the display apparatus according to another embodiment of the present disclosure, except for the configuration in which a driving thin film transistor Dr-TFT, a storage capacitor Cst, and a data line DL to which a data voltage Vdata is applied are disposed on the wiring substrate M-SUB, are the same as those of FIGS. 4 to 6. Therefore, components denoted by the same reference numerals as those in FIGS. 4 to 6 can be briefly described or omitted.

Referring to FIGS. 8, 9 and 10, the link wirings LL and the gate driver GIA can be disposed on the light emitting part PXA of the wiring substrate M-SUB. The gate driver GIA can supply signals for driving the gate lines. The gate driver GIA can be disposed on the first light emitting part PXA-1 positioned in the first block of the wiring substrate M-SUB and the second light emitting part PXA-2 positioned in the second block of the wiring substrate M-SUB in a unit of block. The gate driver GIA can have the size of the first width W1. The gate drivers GIA disposed in adjacent blocks can be electrically connected through a horizontal connection wiring CL.

The thin film transistor Dr-TFT functioning as the driving transistor together with the gate driver GIA, the storage capacitor Cst, and the data line DL to which the data voltage Vdata is applied can be disposed on the light emitting part PXA of the wiring substrate M-SUB on which the gate driver GIA is disposed.

The thin film transistor Dr-TFT can drive the light emitting element ED, and the storage capacitor Cst can store a voltage so that the light emitting element ED continuously maintains the same state for one frame. The thin film transistor Dr-TFT can include a semiconductor layer ACT, a gate electrode GE, a source electrode SE, and a drain electrode DE. A bonding member contact hole 320H can be disposed to overlap the source electrode SE and the drain electrode DE. The source electrode SE and the drain electrode DE can be electrically connected to the bonding member 320 disposed on the display unit TU through the bonding member contact hole 320H.

The data voltage (data voltage line) Vdata can transmit a data signal to the thin film transistor Dr-TFT through the data line DL extending in one direction of the light emitting part PXA of the wiring substrate M-SUB. A scan line SL1 can be disposed to cross the data line DL. In addition, a first transistor Ti to which the data voltage Vdata is applied can be disposed at a position at which the data line DL and the scan line SL1 cross.

The storage capacitor Cst can include a lower capacitor electrode and an upper capacitor electrode. The lower capacitor electrode of the storage capacitor Cst can include the same material as the semiconductor layer ACT, and the upper capacitor electrode of the storage capacitor Cst can include the same material as the gate electrode GE of the thin film transistor Dr-TFT.

The data line DL through the data signal that determines a current value of the thin film transistor Dr-TFT for driving the light emitting element, and the first transistor Ti to which the data voltage Vdata is applied are disposed on the wiring substrate M-SUB. In addition, by arranging the thin film transistor Dr-TFT occupying the large design area and the storage capacitor Cst on the wiring substrate M-SUB, it is possible to additionally secure a margin for sizes of the thin film transistor Dr-TFT and the storage capacitor Cst.

Referring to FIGS. 11 to 13, the light emitting element ED disposed in the pixel area PX and the bonding member 320 can be disposed on the display unit TU. By arranging the thin film transistor Dr-TFT occupying the large design area and the storage capacitor Cst on the wiring substrate M-SUB, it is possible to reduce the areas of circuit elements disposed on the display unit TU. Therefore, it is possible to increase the transmittance of the display unit TU, thereby easily implementing the transparent display apparatus that provides a high resolution and a high transmittance.

As shown in FIG. 12, a reference voltage line VL can be disposed on the display unit TU in one direction (e.g., first direction) of the display unit TU. A scan line SL2, a scan line SL1, and a light emitting signal line EM can be disposed in the other direction (e.g., second direction) crossing the one direction in which the reference voltage line VL is disposed. The first and second directions are perpendicular or substantially perpendicular to each other. The light emitting signal line EM is a wiring to which the light emitting signal is applied, and can be disposed parallel to the scan line SL2. Driving signals can be supplied to the light emitting element ED according to the light emitting signal transmitted to the light emitting signal line EM.

A plurality of bonding members 320 electrically connected to the semiconductor layer ACT (e.g., of the thin film transistor Dr-TFT) can be disposed on the display unit TU. Each of the plurality of bonding members 320 can receive the driving signals from the thin film transistor Dr-TFT through the bonding member contact hole 320H disposed in the wiring substrate M-SUB.

A current value Ioled of the thin film transistor Dr-TFT for driving the light emitting element ED can be determined by a reference voltage Vref and the data voltage Vdata. The current value Ioled can be determined by [Equation 1] below.

$$Ioled = k / 2 * ( Vref - Vdata ) 2 \qquad [ Equation 1 ]$$

In the above, k is a constant.

According to [Equation 1], only when the reference voltage Vref and the data voltage Vdata are supplied uniformly, the current value Ioled of the thin film transistor Dr-TFT for driving the light emitting element can be supplied at a uniform value to stably supply an image. When the reference voltage Vref and the data voltage Vdata are changed, a crosstalk phenomenon in which a distortion can occur in the image can occur due to the influence of coupling or the like. The crosstalk phenomenon can degrade image quality, thereby reducing the reliability of the display apparatus.

In contrast, in another embodiment of the present disclosure, the data voltage Vdata is one of variables that determines the current value Ioled of the thin film transistor Dr-TFT for driving the light emitting element, the data line DL to which the data voltage Vdata is applied can be disposed on the wiring substrate M-SUB, and the reference voltage line VL to which the reference voltage Vref is applied can be disposed separately on the display unit TU. Therefore, it is possible to minimize a coupling effect between the reference voltage Vref and the data voltage Vdata, thereby preventing the occurrence of the crosstalk phenomenon.

As such, the embodiments of the present disclosure provide an improved display apparatus that can address issues associated with a display apparatus of a related art, and can provide at least the following advantages and benefits.

As such, according to one or more embodiments of the present disclosure, it is possible to implement the large-area transparent display apparatus by arranging the plurality of display units on the upper surface of the wiring substrate on which the plurality of link wirings and the gate driver are disposed to overlap each other.

In addition, by introducing the configuration in which the gate driver is disposed on the light emitting part of the wiring substrate at the position overlapping the light emitting part of the display unit, it is possible to prevent the occurrence of the dim defect or issue in which the boundary area between the adjacent display units may be visible to the user.

Therefore, it is possible to implement the zero bezel area in which the bezel area outside the display unit is disposed as the minimum space or the bezel area is not substantially present.

In addition, by introducing the configuration in which the gate driver is disposed on the light emitting part of the wiring substrate at the position overlapping the light emitting part of the display unit, it is possible to prevent the reduction in transmittance due to the reduction in transparent area.

In addition, since the gate driver disposed on the wiring substrate has the smaller size than the pixel area of the display unit and the area including the bonding member, it is possible to prevent the reduction in aperture ratio. Therefore, it is possible to further prevent the reduction in power consumption.

In addition, since the wiring substrate and the plurality of display units are electrically connected on the upper and lower portions thereof using the bonding member without using the separate side wiring, it is possible to achieve process optimization in manufacturing the display apparatus.

The effects and advantages of the present disclosure are not limited to the above-described effects and advantages, and other effects and advantages that are not mentioned will be able to be clearly understood by those skilled in the art from the following description.

According to an embodiment of the present disclosure, a display apparatus comprising: a wiring substrate including a first light emitting part and a first transmissive area; a plurality of display units including a second light emitting part and a second transmissive area and disposed to be spaced apart from each other on the wiring substrate; and a plurality of bonding members disposed between the display units and the wiring substrate and connected to a plurality of link wirings, wherein the plurality of link wirings and a gate driver are disposed on the first light emitting part, and a plurality of light emitting elements are disposed on the second light emitting part.

Further, according to an embodiment of the present disclosure, wherein the wiring substrate is formed of one substrate and the plurality of display units are arranged to be spaced apart from each other in a horizontal direction and a vertical direction on the wiring substrate.

Further, according to an embodiment of the present disclosure, wherein the first light emitting part faces and overlaps the second light emitting part, and the first transmissive area faces and overlaps the second transmissive area.

Further, according to an embodiment of the present disclosure, wherein the gate driver disposed on the first light emitting part is disposed at a position overlapping the second light emitting part.

Further, according to an embodiment of the present disclosure, wherein the gate driver disposed on the first light emitting part has a smaller width than the second light emitting part.

Further, according to an embodiment of the present disclosure, further comprising a horizontal connection wiring connecting the plurality of gate drivers disposed on the first light emitting part in a unit of block.

Further, according to an embodiment of the present disclosure, wherein the bonding member includes: a spacer pattern configured to maintain a gap between the wiring substrate and the display units; a conductive connection pattern configured to cover an upper surface and an outer surface of the spacer pattern; and an adhesive pattern positioned on the conductive connection pattern and connected to the link wiring or the gate driver.

Further, according to an embodiment of the present disclosure, wherein each of the display units includes: a second substrate; a light shielding layer disposed over the second substrate; a thin film transistor positioned on the light shielding layer and including a semiconductor layer, a gate electrode, a source electrode, and a drain electrode; a storage capacitor positioned on the light shielding layer; a planarization layer configured to cover the thin film transistor and the storage capacitor; and a light emitting element disposed on the planarization layer.

Further, according to an embodiment of the present disclosure, wherein the light emitting element includes: a plurality of main light emitting elements; and a plurality of redundancy light emitting elements each corresponding to each of the plurality of main light emitting elements to emit light of the same color.

Further, according to an embodiment of the present disclosure, wherein the wiring substrate further includes a thin film transistor and a storage capacitor disposed on the first light emitting part.

Further, according to an embodiment of the present disclosure, wherein the wiring substrate further includes a data line disposed on the first light emitting part and extending in one direction of the first light emitting part, a data voltage is applied to the data line, and the second light emitting part further includes a reference voltage line disposed in one direction.

Although the embodiments of the present disclosure have been described in more detail with reference to the accompanying drawings, the present disclosure is not necessarily limited to these embodiments, and various modifications can be carried out without departing from the technical spirit of the present disclosure. Therefore, the embodiments disclosed in the present disclosure are not intended to limit the technical spirit of the present disclosure, but for describing it, and the scope of the technical spirit of the present disclosure is not limited by these embodiments. Therefore, it should be understood that the above-described embodiments are illustrative and not restrictive in any and all respects.

What is claimed is:

1. A display apparatus comprising:
a wiring substrate including a first light emitting part and a first transmissive area;
a plurality of display units disposed on the wiring substrate, wherein one display unit among the of the plurality of display units includes a second light emitting part and a second transmissive area;
a plurality of bonding members disposed between the one display unit and the wiring substrate, and electrically connected to a plurality of link wirings; and
a gate driver configured to supply a signal to the one display unit,
wherein the first light emitting part of the wiring substrate includes the plurality of link wirings and the gate driver disposed thereon, and
wherein the second light emitting part of the one display unit includes a plurality of light emitting elements disposed thereon.

2. The display apparatus of claim 1, wherein the wiring substrate is formed of one substrate, and the plurality of display units are arranged to be spaced apart from each other in a first direction and a second direction crossing the first direction on the wiring substrate.

3. The display apparatus of claim 1, wherein the first light emitting part of the wiring substrate faces and overlaps the second light emitting part of the one display unit, and
wherein the first transmissive area of the wiring substrate faces and overlaps the second transmissive area of the one display unit.

4. The display apparatus of claim 1, wherein the gate driver disposed on the first light emitting part of the wiring substrate is disposed at a position overlapping the second light emitting part of the one display unit.

5. The display apparatus of claim 1, wherein the gate driver disposed on the first light emitting part has a size or width smaller width than that of the second light emitting part of the one display unit.

6. The display apparatus of claim 1, further comprising:
a connection wiring connecting the gate driver to an adjacent gate driver disposed on the wiring substrate in a unit of block.

7. The display apparatus of claim 1, wherein one of the plurality of bonding members includes:
a spacer pattern configured to maintain a gap between the wiring substrate and the one display unit;
a conductive connection pattern configured to cover an upper surface and a side surface of the spacer pattern; and
an adhesive pattern disposed on the conductive connection pattern, and electrically connected to the gate driver or one of the plurality of link wirings.

8. The display apparatus of claim 1, wherein the one display unit includes:
a second base substrate;
a light shielding layer disposed on the second base substrate;
a thin film transistor disposed on the light shielding layer, and including a semiconductor layer, a gate electrode, a source electrode, and a drain electrode;
a storage capacitor disposed on the light shielding layer;
a planarization layer covering the thin film transistor and the storage capacitor; and
a light emitting element disposed on the planarization layer and being one of the plurality of light emitting elements.

9. The display apparatus of claim 8, wherein the light emitting element includes:
one or more main light emitting elements; and
a redundancy light emitting element corresponding to each of the one or more main light emitting elements to emit light of a same color.

10. The display apparatus of claim 1, wherein the wiring substrate further includes a thin film transistor and a storage capacitor disposed on the first light emitting part.

11. The display apparatus of claim 10, wherein the wiring substrate further includes a data voltage line disposed on the first light emitting part and a data line extending in one direction of the first light emitting part, and
wherein the second light emitting part further includes a reference voltage line disposed in another direction crossing the one direction.

12. The display apparatus of claim 10, wherein the data voltage line, the plurality of link wirings and the gate driver extend in a same direction on the first light emitting part of the wiring substrate.

13. The display apparatus of claim 1, wherein the plurality of light emitting elements are micro organic light emitting diodes (micro LEDs).

14. A display apparatus comprising:
a wiring substrate including light emitting areas and transmissive areas disposed in an alternating manner;
a plurality of display units disposed on the wiring substrate, and connected with the wiring substrate via at least one bonding member;
a plurality of link lines provided to correspond with each of the plurality of display units, and disposed between the plurality of display units and the wiring substrate; and
a plurality of gate drivers provided to correspond with each of the plurality of display units, and disposed between the plurality of display units and the wiring substrate,
wherein one of the plurality of gate drivers and one or more of the plurality of link lines are disposed in one of the light emitting areas.

15. The display apparatus of claim 14, further comprising:
a plurality of printed circuit boards disposed at opposing sides of the wiring substrate,
wherein the plurality of link lines and the plurality of gate drivers extend in one same direction between the plurality of printed circuit boards.

16. The display apparatus of claim 14, wherein the plurality of display units are arranged in horizontal and vertical directions in a tile manner, and contact each other to form a larger display area.

17. The display apparatus of claim 14, further comprising:
at least one connecting line for electrically connecting the plurality of gate drivers disposed in the one of the light emitting areas to each other.

18. The display apparatus of claim 17, wherein the at least one connecting line extends in a direction that is substantially perpendicular to a direction along which the one of the plurality of gate drivers and the one or more of the plurality of link lines extend in the one of the light emitting areas.

19. The display apparatus of claim 14, wherein each of the plurality of display units includes:
a plurality of main light emitting elements configured to emit light of different colors; and
a plurality of redundancy light emitting elements corresponding to the plurality of main light emitting elements.

20. The display apparatus of claim 19, wherein the at least one bonding member includes a plurality of bonding members corresponding to the plurality of main light emitting elements and the plurality of redundancy light emitting elements, and disposed in the one of the light emitting areas.
